(19) United States
(12) Patent Application Publication
(10) Pub. No.: US 2026/0107740 A1
(43) Pub. Date: Apr. 16, 2026

(54) METHOD OF FABRICATING SEMICONDUCTOR PACKAGE USING PARAFFIN-BASED FIXING FILM

(71) Applicant: SAMSUNG ELECTRONICS CO., LTD., Suwon-si (KR)

(72) Inventor: Hyungjun KIM, suwon-si (KR)

(73) Assignee: SAMSUNG ELECTRONICS CO., LTD., Suwon-si (KR)

(21) Appl. No.: 19/191,639

(22) Filed: Apr. 28, 2025

(30) Foreign Application Priority Data
Oct. 11, 2024 (KR) 10-2024-0138869

(51) Int. Cl. H01L 21/683; H01L 21/56

(52) U.S. Cl. CPC H10P 72/7402; H10W 74/019

(57) ABSTRACT

A method of fabricating a semiconductor package includes preparing a semiconductor device including a plurality of step structures, covering, at a first temperature, a portion of the plurality of step structures with a fixing film, fixing the fixing film on the portion of the plurality of step structures by performing, at a second temperature, an annealing process on the fixing film, and separating, at a third temperature, at least a portion of the fixing film from the semiconductor device. Each of the first temperature and the third temperature is greater than the second temperature. The fixing film includes a paraffin-based compound. The fixing film at each of the first temperature and the third temperature has an elastic modulus less than an elastic modulus of the fixing film at the second temperature.

### CROSS-REFERENCE TO RELATED APPLICATIONS

This application claims benefit of priority under 35 U.S.C § 119 to Korean Patent Application No. 10-2024-0138869, filed on Oct. 11, 2024, in the Korean Intellectual Property Office, the disclosure of which is incorporated by reference herein in its entirety.

### BACKGROUND

### 1. Field

The present disclosure relates generally to semiconductor packages, and more particularly, to a method of fabricating a semiconductor package.

### 2. Descript of Related Art

A semiconductor package may be provided to implement an integrated circuit chip that may be suitable for use in electronic products. A semiconductor package may be configured such that a semiconductor chip may be mounted on a printed circuit board, and bonding wires and/or bumps may be used to electrically connect the semiconductor chip to the printed circuit board. However, there exists a need for further improvements in semiconductor package technology, as the need for semiconductor packages for use in electronic products may be constrained by reliability and durability of semiconductor packages. Improvements are presented herein. These improvements may also be applicable to other semiconductor technologies.

### SUMMARY

One or more example embodiments of the present disclosure provide a semiconductor package with improved productivity, when compared to related semiconductor packages.

Further, one or more example embodiments of the present disclosure provide a simplified method of fabricating a semiconductor package and a semiconductor package fabricated using the same.

The object of the present disclosure is not limited to the mentioned above, and other objects which have not been mentioned above may be understood to those skilled in the art from the following description.

According to an aspect of the present disclosure, a method of fabricating a semiconductor package includes preparing a semiconductor device including a plurality of step structures, covering, at a first temperature, a portion of the plurality of step structures with a fixing film, fixing the fixing film on the portion of the plurality of step structures by performing, at a second temperature, an annealing process on the fixing film, and separating, at a third temperature, at least a portion of the fixing film from the semiconductor device. Each of the first temperature and the third temperature is greater than the second temperature. The fixing film includes a paraffin-based compound. The fixing film at each of the first temperature and the third temperature has an elastic modulus less than an elastic modulus of the fixing film at the second temperature.

According to an aspect of the present disclosure, a method of fabricating a semiconductor package includes preparing a semiconductor device including a plurality of step structures, covering, at a first temperature, a portion of the plurality of step structures with a fixing film, fixing the fixing film on the portion of the plurality of step structures by performing, at a second temperature, an annealing process on the fixing film, and separating, at a third temperature, at least a portion of the fixing film from the semiconductor device. The fixing film includes a paraffin-based compound. A thickness of the fixing film has a range of 50 micrometers (μm) to 500 μm. A carbon number of the fixing film has a range of 15 to 150.

According to an aspect of the present disclosure, a method of fabricating a semiconductor package includes forming a chip stack including a plurality of semiconductor chips that are stepwise stacked along a first direction, providing, at a first temperature, the chip stack on a surface of a fixing film, fixing the chip stack to the fixing film by annealing, at a second temperature, the fixing film, forming a plurality of wires on the chip stack, forming a molding layer at least partially covering the chip stack, forming a redistribution pattern on the molding layer, forming a plurality of connection terminals on the redistribution pattern, and separating, at a third temperature, at least a portion of the fixing film from the chip stack. The fixing film includes a paraffin-based compound. Each of the first temperature and the third temperature is greater than the second temperature. The second temperature is less than a softening point of the fixing film.

Additional aspects may be set forth in part in the description which follows and, in part, may be apparent from the description, and/or may be learned by practice of the presented embodiments.

### BRIEF DESCRIPTION OF DRAWINGS

The above and other aspects, features, and advantages of certain embodiments of the present disclosure may be more apparent from the following description taken in conjunction with the accompanying drawings, in which:

FIG. 1 illustrates a flow chart showing a method of fabricating a semiconductor package, according to some embodiments of the present disclosure;

FIGS. 2 to 5 illustrate cross-sectional views showing a method of fabricating a semiconductor package, according to some embodiments of the present disclosure;

FIG. 6 illustrates a cross-sectional view showing a method of fabricating a semiconductor package, according to some embodiments of the present disclosure;

FIG. 7 illustrates a cross-sectional view showing a method of fabricating a semiconductor package, according to a comparative example.

FIG. 8A illustrates a cross-sectional view showing a semiconductor package, according to some embodiments of the present disclosure;

FIGS. 8B and 8C illustrate cross-sectional views showing a method of fabricating the semiconductor package according to FIG. 8A, according to some embodiments of the present disclosure.

### DETAILED DESCRIPTION OF EMBODIMENTS

The following description with reference to the accompanying drawings is provided to assist in a comprehensive understanding of embodiments of the present disclosure defined by the claims and their equivalents. Various specific details are included to assist in understanding, but these details are considered to be exemplary only. Therefore, those of ordinary skill in the art may recognize that various changes and modifications of the embodiments described herein may be made without departing from the scope and spirit of the disclosure. In addition, descriptions of well-known functions and structures are omitted for clarity and conciseness.

With regard to the description of the drawings, similar reference numerals may be used to refer to similar or related elements. It is to be understood that a singular form of a noun corresponding to an item may include one or more of the things, unless the relevant context clearly indicates otherwise. As used herein, each of such phrases as “A or B,” “at least one of A and B,” “at least one of A or B,” “A, B, or C,” “at least one of A, B, and C,” and “at least one of A, B, or C,” may include any one of, or all possible combinations of the items enumerated together in a corresponding one of the phrases. As used herein, such terms as “1st” and “2nd,” or “first” and “second” may be used to simply distinguish a corresponding component from another, and does not limit the components in other aspect (e.g., importance or order). It is to be understood that if an element (e.g., a first element) is referred to, with or without the term “operatively” or “communicatively”, as “coupled with,” “coupled to,” “connected with,” or “connected to” another element (e.g., a second element), it means that the element may be coupled with the other element directly (e.g., wired), wirelessly, or via a third element.

It is to be understood that when an element or layer is referred to as being “over,” “above,” “on,” “below,” “under,” “beneath,” “connected to” or “coupled to” another element or layer, it may be directly over, above, on, below, under, beneath, connected or coupled to the other element or layer or intervening elements or layers may be present. In contrast, when an element is referred to as being “directly over,” “directly above,” “directly on,” “directly below,” “directly under,” “directly beneath,” “directly connected to” or “directly coupled to” another element or layer, there are no intervening elements or layers present.

The terms “upper,” “middle”, “lower”, and the like may be replaced with terms, such as “first,” “second,” third” to be used to describe relative positions of elements. The terms “first,” “second,” third” may be used to describe various elements but the elements are not limited by the terms and a “first element” may be referred to as a “second element”. Alternatively or additionally, the terms “first”, “second”, “third”, and the like may be used to distinguish components from each other and do not limit the present disclosure. For example, the terms “first”, “second”, “third”, and the like may not necessarily involve an order or a numerical meaning of any form.

As used herein, when an element or layer is referred to as “covering”, “overlapping”, or “surrounding” another element or layer, the element or layer may cover at least a portion of the other element or layer, where the portion may include a fraction of the other element or may include an entirety of the other element. Similarly, when an element or layer is referred to as “penetrating” another element or layer, the element or layer may penetrate at least a portion of the other element or layer, where the portion may include a fraction of the other element or may include an entire dimension (e.g., length, width, depth) of the other element.

Reference throughout the present disclosure to “one embodiment,” “an embodiment,” “an example embodiment,” or similar language may indicate that a particular feature, structure, or characteristic described in connection with the indicated embodiment is included in at least one embodiment of the present solution. Thus, the phrases “in one embodiment”, “in an embodiment,” “in an example embodiment,” and similar language throughout this disclosure may, but do not necessarily, all refer to the same embodiment. The embodiments described herein are example embodiments, and thus, the disclosure is not limited thereto and may be realized in various other forms.

It is to be understood that the specific order or hierarchy of blocks in the processes/flowcharts disclosed are an illustration of exemplary approaches. Based upon design preferences, it is understood that the specific order or hierarchy of blocks in the processes/flowcharts may be rearranged. Further, some blocks may be combined or omitted. The accompanying claims present elements of the various blocks in a sample order, and are not meant to be limited to the specific order or hierarchy presented.

In the present disclosure, the articles “a” and “an” are intended to include one or more items, and may be used interchangeably with “one or more.” Where only one item is intended, the term “one” or similar language is used. For example, the term “a semiconductor package” may refer to either a single semiconductor package or multiple semiconductor package. When a semiconductor package is described as carrying out an operation and the semiconductor package is referred to perform an additional operation, the multiple operations may be executed by either a single semiconductor package or any one or a combination of semiconductor packages.

Hereinafter, various embodiments of the present disclosure are described with reference to the accompanying drawings.

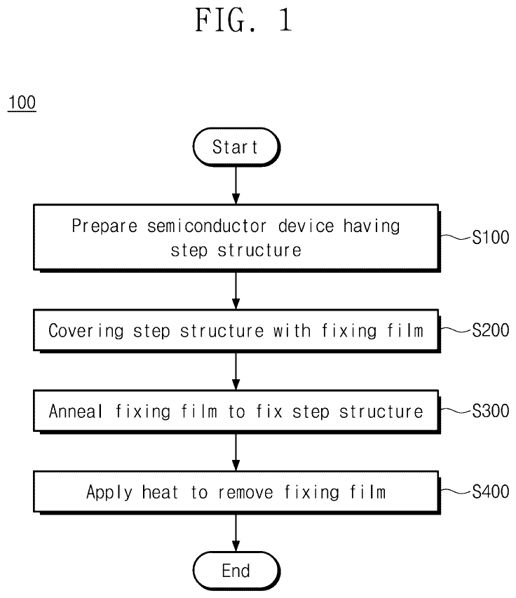

FIG. 1 illustrates a flow chart showing a method of fabricating a semiconductor package, according to some embodiments of the present disclosure.

Referring to FIG. 1, the method 100 of fabricating a semiconductor package, according to the present disclosure, may include preparing a semiconductor device having a step structure (operation S100), covering the step structure with a fixing film (operation S200), annealing the fixing film to fix the step structure (operation S300), and applying heat to remove the fixing film (operation S400).

A plurality of step structures may be provided on a surface of the semiconductor device. The fixing film may be provided on the surface of the semiconductor device having the step structure. The fixing film may be annealed to fix the step structure. The semiconductor device fixed by the fixing film may be transported to undergo a subsequent process.

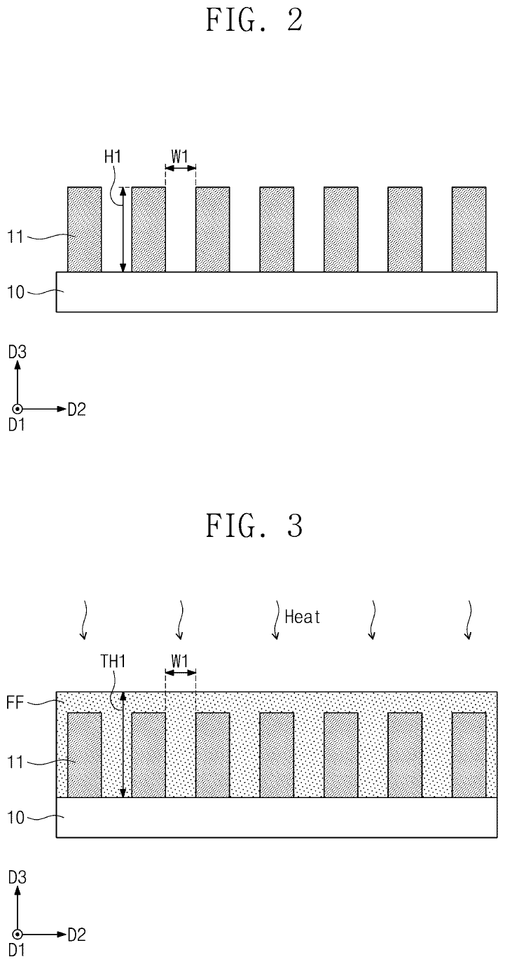

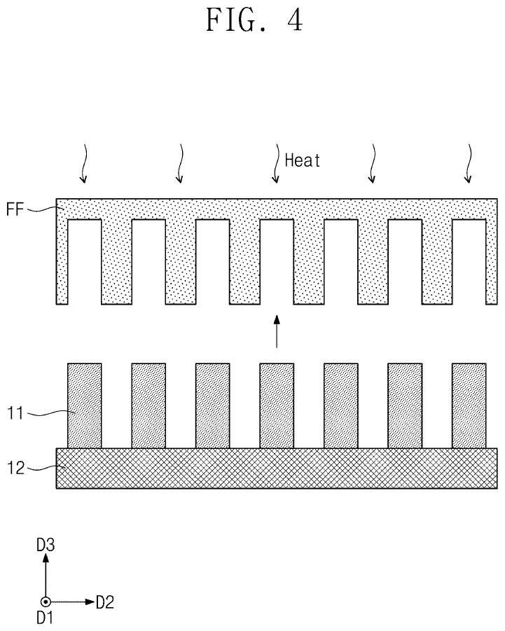

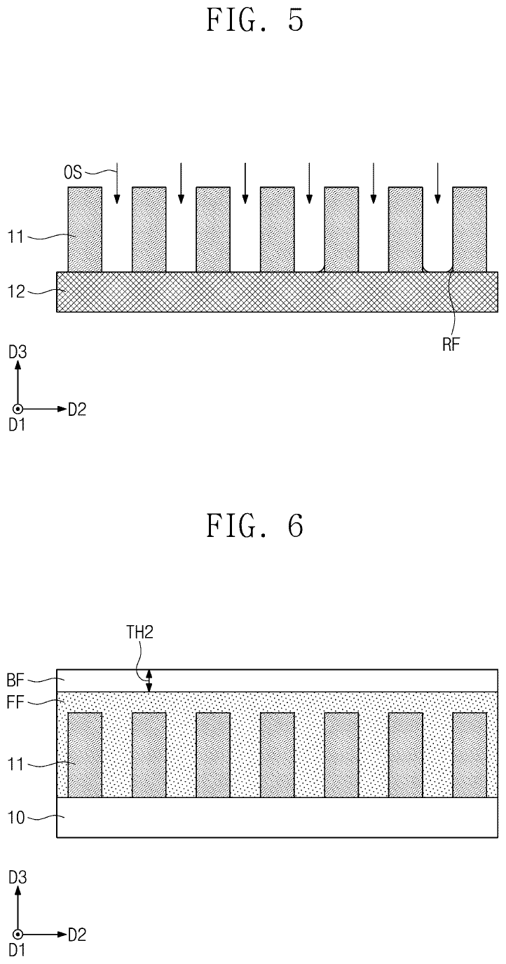

FIGS. 2 to 5 illustrate cross-sectional views showing a method of fabricating a semiconductor package, according to some embodiments of the present disclosure. A method of fabricating a semiconductor package according to FIG. 1 is described with reference to FIGS. 2 to 5. For example, the operation S100 of FIG. 1 is described with reference to FIG. 2. The operations S200 and S300 are described with reference to FIG. 3. The operation S400 is described with reference to FIG. 4.

As used herein, D1 may be referred to as a first direction, D2 may be referred to as a second direction orthogonal to the first direction D1, and D3 may be referred to as a third direction perpendicular to the first direction D1 and the second direction D2.

Referring to FIG. 2, a plurality of step structures 11 may be provided on a substrate 10. The substrate 10 may be, but not be limited to, a surface of the semiconductor device. The plurality of step structures 11 may be at least one of one or more components forming one or more step differences on the surface of the semiconductor device (e.g., the substrate 10). In an embodiment, at least one layer may further be provided between the substrate 10 and the plurality of step structures 11.

The plurality of step structures 11 may have a first height H1. The plurality of step structures 11 may form a step difference with a top surface of the substrate 10. The plurality of step structures 11 may be and/or may include structures that may form a step difference with the top surface of the substrate 10. A pair of adjacent step structures of the plurality of step structures 11 may be spaced apart from each other. In an embodiment, a distance between the pair of adjacent step structures of the plurality of step structures 11 may be a first width W1.

In an embodiment, the substrate 10 and the plurality of step structures 11 may include and/or may be formed using materials that may be different from each other. However, the present disclosure is not limited thereto. Alternatively or additionally, the plurality of step structures 11 may be and/or may include protruding portions of the substrate 10.

A ratio of the width W1 between the plurality of step structures 11 to the first height H1 of the plurality of step structures 11 may range from about 3 to about 10. That is, the plurality of step structures 11 may have an aspect ratio of about 3 to about 10.

Referring to FIG. 3, a fixing film FF may be provided on the substrate 10 and the plurality of step structures 11. The fixing film FF may cover a top surface of the substrate 10, and may also cover top surfaces and opposite sidewalls of the plurality of step structures 11. Additionally, the fixing film FF may be provided between adjacent steps of the plurality of step structures 11.

The covering of the substrate 10 and the plurality of step structures 11 with the fixing film FF may be performed at a first temperature. The first temperature may be greater than room temperature (e.g., approximately 20 degrees Celsius (°C.) to 25° C.). The first temperature may be maintained by applying heat to the fixing film FF, as shown in FIG. 3. The first temperature may be greater than a softening point of the fixing film FF and less than a melting point of the fixing film FF.

The fixing film FF at the first temperature may not be a rigid solid, but may be a solid having viscoelasticity. For example, the fixing film FF at the first temperature may have waxy properties. The fixing film FF at the first temperature may exhibit softness, ductility, partial crystallinity, and/or partial amorphousness. Thus, the fixing film FF may be impregnated between the plurality of step structures 11 without producing voids between the fixing film FF and the plurality of step structures 11. For example, the fixing film FF may be impregnated without empty spaces on the surface of the semiconductor device (e.g., substrate 10) with a large step difference. The fixing film FF may have cohesion, and may be a solid interposed between the plurality of step structures 11.

The fixing film FF may have a maximum thickness TH1 of about 50 micrometers (μm) to about 500 μm. When the fixing film FF has a thickness TH1 of less than about 50 μm (e.g., TH1<50 μm), the fixing film FF may be smaller than the height H1 of the plurality of step structures 11, and thus, may not cover all of the plurality of step structures 11. In such an example, the plurality of step structures 11 may not be stably fixed. Alternatively or additionally, when the fixing film FF has a thickness TH1 of greater than about 500 μm (e.g., TH1>500 μm), the fixing film FF may not be sufficiently annealed in a subsequent annealing process described with reference to FIG. 3, and thus, the plurality of step structures 11 may not be stably fixed.

The fixing film FF may include a paraffin-based compound. For example, the fixing film FF may include, but not be limited to, at least one of n-paraffin, iso-paraffin, cyclo-paraffin, microcrystalline paraffin, or a combination thereof. For example, the fixing film FF may include a fine crystal.

Alternatively or additionally, the fixing film FF may include a combination of a paraffin-based compound and a heterocyclic compound. A ratio of the paraffin compound and the heterocyclic compound may be controlled to appropriately adjust the softening point and/or the melting point of the fixing film FF. The softening point of the fixing film FF may range from about 60° C. to about 90° C.

The fixing film FF may have a carbon number of about 15 to about 150. An increase in carbon number of the fixing film FF may cause an increase in length of carbon chains of the fixing film FF. When the fixing film FF has a carbon number of less than about 15, the fixing film FF may exhibit reduced stability and degraded cohesion. Therefore, the fixing film FF may induce unstable fixation of the plurality of step structures 11. In addition, the fixing film FF may suffer from fracture in a subsequent separation procedure of the fixing film FF described with reference to FIG. 4. Alternatively or additionally, when the fixing film FF has a carbon number of greater than about 150, the fixing film FF may have a high softening point and thus physical properties of the fixing film FF may be less sensitive to temperature changes, which may result in a reduction in process stability. Accordingly, the fixing film FF may not effectively fix the plurality of step structures 11.

Subsequent to the fixing film FF is impregnated between the plurality of step structures 11, an annealing process may be performed on the fixing film FF. The annealing process may be performed at a second temperature. The second temperature may be less than the softening point of the fixing film FF. The second temperature may be less than the first temperature. The fixing film FF at the second temperature may have an elastic modulus greater than that of the fixing film FF at the first temperature. For example, the fixing film FF at the second temperature may experience less deformation from external force compared to the fixing film FF at the first temperature. The fixing film FF at the second temperature may have a rigidity greater than that of the fixing film FF at the first temperature. Therefore, the fixing film FF may induce stable fixation of the plurality of step structures 11. The fixing film FF may serve as a support for the substrate 10 and the plurality of step structures 11.

Referring to FIG. 4, the plurality of step structures 11 and the substrate 10 may be fixed by the fixing film FF, and a subsequent process may be performed. For example, the substrate 10 may be changed into a subsequent substrate 12. That is, one or more subsequent processes may be executed on the fixed semiconductor device that has been fixed by the fixing film FF. However, the present disclosure is not limited thereto.

After performing subsequent processes, the fixing film FF may be separated from the subsequent substrate 12 and the plurality of step structures 11. The separation of the fixing film FF may be performed at a third temperature. The third temperature may be greater than the second temperature. The third temperature may be maintained by applying heat to the fixing film FF, as shown in FIG. 4. The third temperature may be greater than the softening point of the fixing film FF and less than the melting point of the fixing film FF.

The fixing film FF at the third temperature may not be a rigid solid, but may be a solid having viscoelasticity. The fixing film FF at the third temperature may have a viscoelasticity less than that of the fixing film FF at the first temperature. The fixing film FF at the third temperature may have an elastic modulus less than an elastic modulus of the fixing film FF at the second temperature. For example, the fixing film FF at the third temperature may be deformed to a greater extent from an external force when compared to a deformation of the fixing film FF at the second temperature due to the same external force. The fixing film FF at the third temperature may have a rigidity less than a rigidity of the fixing film FF at the second temperature. Consequently, the fixing film FF may be separated from the plurality of step structures 11 while preventing and/or reducing a likelihood of damage to the plurality of step structures 11. In some embodiments, the separated fixing film FF may be reused after being separated from the plurality of step structures 11.

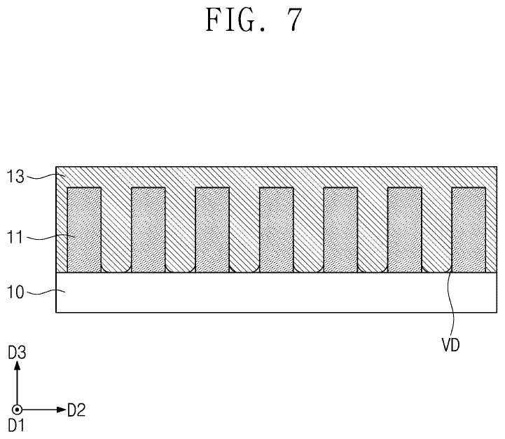

Referring to FIG. 5, subsequent the separation of the fixing film FF, a portion RF of the fixing film FF (e.g., a residual fixing film RF) may remain on a top surface of the subsequent substrate 12 and/or between the plurality of step structures 11. A washing process in which an organic solvent OS is used may be additionally performed to remove the residual fixing film RF. The residual fixing film RF may be dissolved in the organic solvent OS and may be completely removed from the subsequent substrate 12 and the plurality of step structures 11. For example, the fixing film FF may include a material that may be dissolved by the organic solvent OS.

According to the present disclosure, the fixing film FF including a paraffin-based compound may be used to stably fix a semiconductor device having a significant step difference and/or an asymmetric structure. An elastic modulus of the fixing film FF may be changed depending on a temperature. In a heated state at a first temperature, the fixing film FF may be impregnated onto a surface of the semiconductor device, and may be annealed at a second temperature (e.g., room temperature) to fix the semiconductor device. After that, in a reheated state at a third temperature, the fixing film FF may be separated from the semiconductor device without significant damage to the semiconductor device. Thus, the semiconductor device having a significant step difference may be transported while being fixed by the fixing film FF, and a subsequent process may be stably performed on the semiconductor device. In addition, the fixing film FF may be separated without damage to the semiconductor device. Additionally, the fixing film FF of the present disclosure may include a paraffin-based compound, and as such, may be dissolved in an organic solvent, thereby being removed relatively easily. The used fixing film FF may be reusable to further reduce fabricating costs of semiconductor packages.

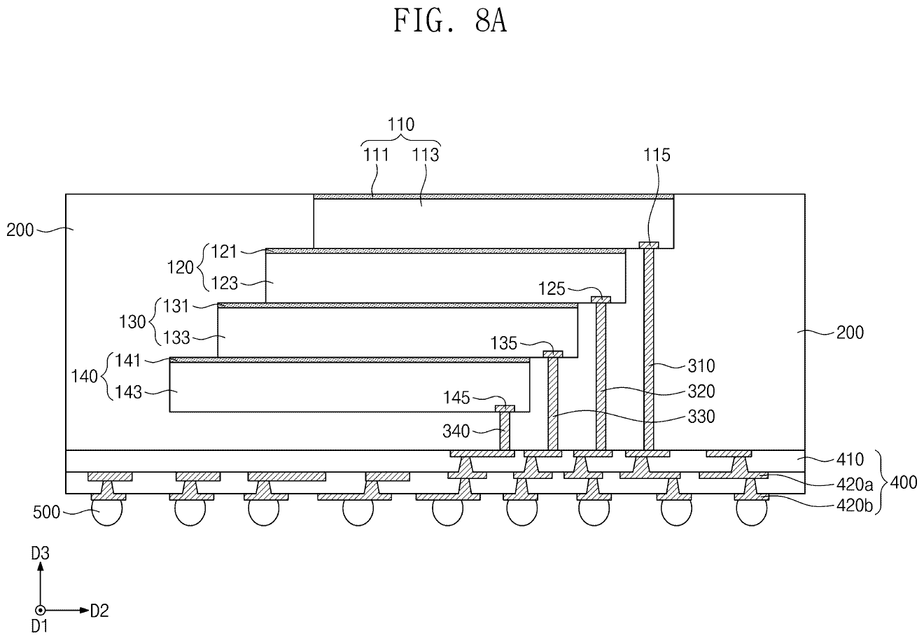

FIG. 6 illustrates a cross-sectional view showing a method of fabricating a semiconductor package, according to some embodiments of the present disclosure. The method of fabricating a semiconductor package of FIG. 6 may include and/or may be similar in many respects to the method of fabricating a semiconductor package described above with reference to FIGS. 2 to 5, and may include additional features not mentioned above. Consequently, the description of the method of fabricating a semiconductor package of FIG. 6 may focus on differences from the method of fabricating a semiconductor package described above with reference to FIGS. 2 to 5, and repeated descriptions of the method of fabricating a semiconductor package of FIG. 6 described above with reference to FIGS. 2 to 5 may be omitted for the sake of brevity.

Referring to FIG. 6, a base film BF may be provided on the fixing film FF. The base film BF may provide to more stably fix the fixing film FF to the plurality of step structures 11. In addition, the base film BF may further facilitate the separation of the fixing film FF.

The base film BF may be and/or may include a polymer material. The base film BF may include, but not be limited to, at least one of polyethylene (PE), polypropylene (PP), polyvinyl chloride (PVC), polyethylene terephthalate (PET), polycarbonate (PC), polyamide (PA), polyolefin (PO), polyethylene naphthalate (PEN), and polyetheretherketone (PEEK). The base film BF may have a thickness TH2 of about 50 μm to about 100 μm.

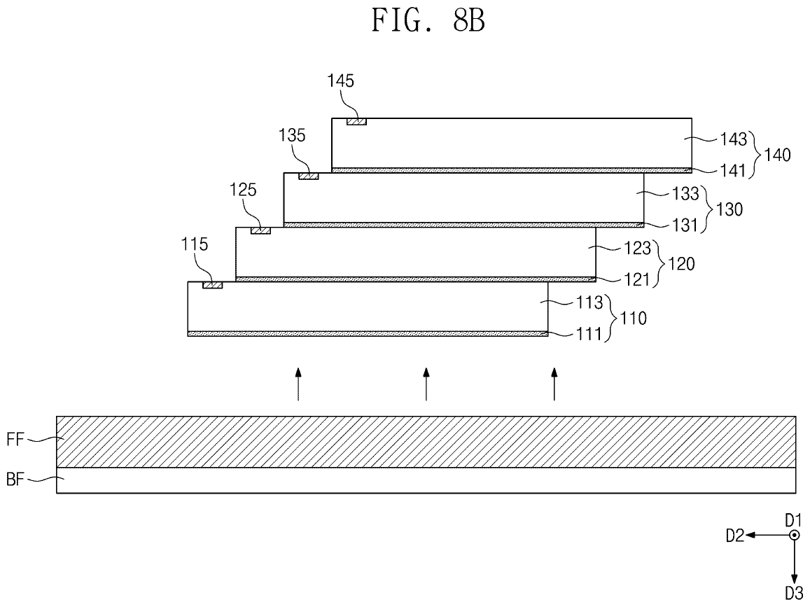

FIG. 7 illustrates a cross-sectional view showing a method of fabricating a semiconductor package, according to a comparative example. The method of fabricating a semiconductor package of FIG. 7 may include and/or may be similar in many respects to the method of fabricating a semiconductor package described above with reference to FIGS. 2 to 5, and may include additional features not mentioned above. Consequently, the description of the method of fabricating a semiconductor package of FIG. 7 may focus on differences from the method of fabricating a semiconductor package described above with reference to FIGS. 2 to 5, and repeated descriptions of the method of fabricating a semiconductor package of FIG. 7 described above with reference to FIGS. 2 to 5 may be omitted for the sake of brevity.

Referring to FIG. 7, when a related pressure sensitive adhesive 13 is impregnated between the plurality of step structures 11, a void VD may be created between the substrate 10 and the pressure sensitive adhesive 13 and/or between the plurality of step structures 11 and the pressure sensitive adhesive 13. The void VD may be formed because the pressure sensitive adhesive 13 may simply adhere to the substrate 10 and the plurality of step structures 11 without any change in temperature-dependent physical properties. As such, the void VD may cause the pressure sensitive adhesive 13 to have a difficulty in stably fixing the substrate 10 and/or the plurality of step structures 11. In addition, when the pressure sensitive adhesive 13 is separated, the void VD may induce fracture of the pressure sensitive adhesive 13 and/or damage to the plurality of step structures 11.

Alternatively or additionally, the fixing film FF, according to the present disclosure, may be inserted (impregnated) between the plurality of step structures 11 without being attached to the substrate 10 and the plurality of step structures 11. Additionally, since physical properties of the fixing film FF may be changed depending on temperature, the fixing film FF may be impregnated without formation of the void VD between the plurality of step structures 11 and the substrate 10. Therefore, even when the semiconductor device has a large step difference, the fixing film FF may stably fix the semiconductor device compared to the pressure sensitive adhesive 13.

Moreover, since the void VD is absent and the fixing film FF exhibits viscoelasticity, the fixing film FF may be separated from the semiconductor device without significant damage to the plurality of step structures 11. The residual fixing film RF may be completely removed by the organic solvent OS.

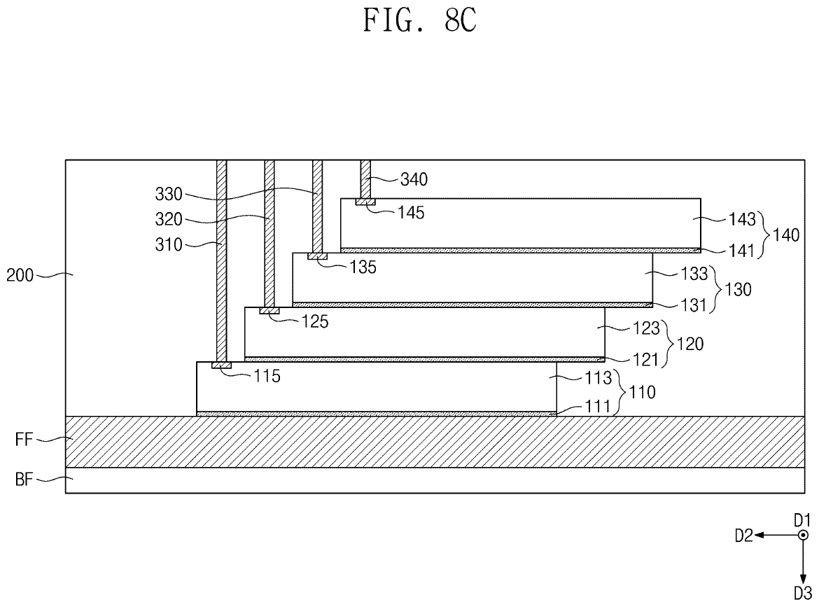

FIG. 8A illustrates a cross-sectional view showing a semiconductor package, according to some embodiments of the present disclosure.

Referring to FIG. 8A, a semiconductor package may include a chip stack including a plurality of semiconductor chips (e.g., a first semiconductor chip 110, a second semiconductor chip 120, a third semiconductor chip 130, and a fourth semiconductor chip 140), a molding layer 200, a plurality of wires (e.g. first wires 310, second wires 320, third wires 330, and fourth wires 340), and a redistribution substrate 400. Each of the plurality of first to fourth wires 310 to 340 may include at least one of a bonding wire or a vertical wire.

The first semiconductor chip 110 may include a first die adhesion layer 111 and a first semiconductor die 113. The second semiconductor chip 120 may include a second die adhesion layer 121 and a second semiconductor die 123. The third semiconductor chip 130 may include a third die adhesion layer 131 and a third semiconductor die 133. The fourth semiconductor chip 140 may include a fourth die adhesion layer 141 and a fourth semiconductor die 143. The first to fourth die adhesion layers 111 to 141 may be disposed on bottom surfaces of the first to fourth semiconductor dies 113 to 143, respectively. For example, each die adhesion layer of the first to fourth die adhesion layers 111 to 141 may include a dielectric adhesive material. Alternatively or additionally, each semiconductor die of the first to fourth semiconductor dies 113 to 143 may include an integrated memory device. Although FIG. 8A depicts the chip stack as having four (4) semiconductor chips, the present disclosure is not limited in this regard. For example, the chip stack may have fewer semiconductor chips (e.g., <4) or may have more semiconductor chips (e.g., >4).

The plurality of first to fourth semiconductor chips 110 to 140 may be sequentially stepwise stacked along a second direction D2. For example, the second semiconductor chip 120 may be stacked offset in the second direction D2 on the first semiconductor chip 110, the third semiconductor chip 130 may be stacked offset in the second direction D2 on the second semiconductor chip 120, and the fourth semiconductor chip 140 may be stacked offset in the second direction D2 on the third semiconductor chip 130.

The plurality of first to fourth semiconductor chips 110 to 140 may include a respective plurality of chip pads (e.g., first chip pads 115, second chip pads 125, third chip pads 135, and fourth chip pads 145). A top surface of the first semiconductor chip 110 may have a portion where the second semiconductor chip 120 does not overlap, and the first chip pads 115 may be placed on the non-overlapping portion. Similarly, top surfaces of the second and third semiconductor chips 120 and 130 may include portions where the third and fourth semiconductor chips 130 and 140 do not overlap, and the second and third chip pads 125 and 135 may be placed on corresponding non-overlapping portions. The fourth chip pads 145 may be disposed on a top surface of the fourth semiconductor chip 140. The plurality of first to fourth chip pads 115 to 145 may each be provided in plural in corresponding semiconductor chips of the plurality of first to fourth semiconductor chips 110 to 140, and the plurality of first to fourth chip pads 115 to 145 placed on their corresponding semiconductor chip may be spaced apart from each other along the first direction D1.

The plurality of first to fourth wires 310 to 340 may connect the chip stack (e.g., the plurality of first to fourth semiconductor chips 110 to 140) to the redistribution substrate 400. For example, the first wires 310 may correspondingly connect the first chip pads 115 of the first semiconductor chip 110 to the redistribution substrate 400, the second wires 320 may correspondingly connect the second chip pads 125 of the second semiconductor chip 120 to the redistribution substrate 400, the third wires 330 may correspondingly connect the third chip pads 135 of the third semiconductor chip 130 to the redistribution substrate 400, and the fourth wires 340 may correspondingly connect the fourth chip pads 145 of the fourth semiconductor chip 140 to the redistribution substrate 400.

The molding layer 200 may cover the chip stack (e.g., the plurality of first to fourth semiconductor chips 110 to 140). The molding layer 200 may cover top and/or lateral surfaces of the chip stack. For example, the molding layer 200 may cover lateral surfaces of the plurality of first to fourth wires 310 to 340. A top surface of the molding layer 200 may be substantially coplanar with those of the plurality of first to fourth wires 310 to 340. For example, the molding layer 200 may include, but not be limited to, at least one of a material such as an epoxy molding compound or an adhesive material.

The redistribution substrate 400 may include a dielectric layer 410 and a plurality of redistribution patterns (e.g., first redistribution patterns 420a and second redistribution patterns 420b). The plurality of first and second redistribution patterns 420a and 420b may be electrically connected to the plurality of first to fourth wires 310 to 340. For example, a portion of the first redistribution patterns 420a may be disposed in the dielectric layer 410, and a portion of the second redistribution patterns 420b may be disposed at an uppermost end and may penetrate a portion of the dielectric layer 410 and protrude onto the dielectric layer 410.

A plurality of package connection terminals 500 may be additionally disposed on the redistribution substrate 400. The plurality of package connection terminals 500 may be connected to the second redistribution patterns 420b positioned at an uppermost end. For example, the plurality of package connection terminals 500 may include, but not be limited to, at least one of tin (Sn), bismuth (Bi), lead (Pb), silver (Ag), or an alloy thereof. The package connection terminal 500 may have a solder ball shape.

FIGS. 8B and 8C illustrate cross-sectional views showing a method of fabricating the semiconductor package according to FIG. 8A, and according to some embodiments of the present disclosure.

Referring to FIG. 8B, a base film BF may be provided, and a fixing film FF may be provided on the base film BF. The base film BF may have a thickness of about 50 μm to about 100 μm. The base film BF may be and/or may include a polymer film. For example, the base film BF may include, but not be limited to, at least one of polyethylene (PE), polypropylene (PP), polyvinyl chloride (PVC), polyethylene terephthalate (PET), polycarbonate (PC), polyamide (PA), polyolefin (PO), polyethylene naphthalate (PEN), and polyetheretherketone (PEEK).

The fixing film FF may have a thickness of about 50 μm to about 500 μm. The fixing film FF may include a paraffin-based compound. For example, the fixing film FF may include, but not be limited to, at least one of n-paraffin, iso-paraffin, cyclo-paraffin, microcrystalline paraffin, and a combination thereof. Alternatively or additionally, the fixing film FF may include a fine crystal.

A chip stack, including a plurality of semiconductor chips (e.g., a first semiconductor chip 110, a second semiconductor chip 120, a third semiconductor chip 130, and a fourth semiconductor chip 140), may be stacked. The stacking of the plurality of first to fourth semiconductor chips 110 to 140 may include stacking the first semiconductor chip 110 on a metal layer, stacking the second semiconductor chip 120 on the first semiconductor chip 110, stacking the third semiconductor chip 130 on the second semiconductor chip 120, and stacking the fourth semiconductor chip 140 on the third semiconductor chip 130.

The plurality of first to fourth semiconductor chips 110 to 140 may be stepwise stacked, and during the stacking procedure, top surfaces of the plurality of first to third semiconductor chips 110 to 130 may be partially exposed. In addition, a plurality of chip pads (e.g., first chip pads 115, second chip pads 125, and third chip pads 135) corresponding to the first to third semiconductor chips 110 to 130 may be exposed through the exposed top surfaces of the first to third semiconductor chips 110 to 130.

The chip stack including the plurality of first to fourth semiconductor chips 110 to 140 may be provided on the fixing film FF. The providing of the fixing film FF may be performed at a first temperature. The first temperature may be greater than a softening point of the fixing film FF and less than a melting point of the fixing film FF.

The fixing film FF at the first temperature may have viscoelasticity. At the first temperature, the fixing film FF may cover a lateral surface of the first semiconductor chip 110. The fixing film FF may cover the lateral surface of the first semiconductor chip 110 because, at the first temperature, the fixing film FF may not be in a rigid solid state, but may have fluidity.

Referring to FIG. 8C, the chip stack including the plurality of first to fourth semiconductor chips 110 to 140 may be fixed onto the fixing film FF. The fixing of the fixing film FF may be performed at a second temperature. The second temperature may be less than the first temperature. The second temperature may be less than the softening point of the fixing film FF. For example, the second temperature may be room temperature.

The fixing film FF at the second temperature may have an elastic modulus greater than an elastic modulus of the fixing film FF at the first temperature. The fixing film FF at the second temperature may have a rigidity greater than a rigidity of the fixing film FF at the first temperature. The fixing film FF at the second temperature may not have viscoelasticity and/or fluidity. The fixing film FF when in a rigid state may robustly fix the chip stack including the plurality of first to fourth semiconductor chips 110 to 140. For example, the chip stack including the plurality of first to fourth semiconductor chips 110 to 140 may have an asymmetric structure and may be stably fixed by the fixing film FF. Therefore, subsequent processes may be stably performed on the chip stack including the plurality of first to fourth semiconductor chips 110 to 140.

A plurality of wires (e.g., first wires 310, second wires 320, third wires 330, and fourth wires 340) may be formed on the fixed chip stack including the plurality of first to fourth semiconductor chips 110 to 140). A molding layer 200 may be formed to cover the chip stack including the plurality of first to fourth semiconductor chips 110 to 140 and the plurality of first to fourth wires 310 to 340. Top surfaces of the plurality of first to fourth wires 310 to 340 may be coplanar with a top surface of the molding layer 200. Each of the plurality of first to fourth wires 310 to 340 may include at least one of a bonding wire or a vertical wire.

Referring back to FIG. 8A, a redistribution substrate 400 may be formed on the top surface of the molding layer 200. The redistribution substrate 400 may be formed by repeatedly forming a dielectric layer 410 and a plurality of redistribution patterns (e.g., first redistribution patterns 420a and second redistribution patterns 420b) that may penetrate the dielectric layer 410. The formation of the first and second redistribution patterns 420a and 420b may include forming the dielectric layer 410, patterning the dielectric layer 410 to form an opening, and forming a metal layer to fill the opening and to cover the dielectric layer 410.

A plurality of package connection terminals 500 may be formed on the redistribution substrate 400. The plurality of package connection terminal 500 may be connected to the second redistribution patterns 420b disposed at a lowermost end.

Subsequently (e.g., after performing subsequent processes), the base film BF and the fixing film FF may be removed. The removal of the fixing film FF may be performed at a third temperature. The third temperature may be greater than the second temperature. The fixing film FF at the third temperature may have viscoelasticity. The fixing film FF at the third temperature may have an elastic modulus less than an elastic modulus of the fixing film FF at the second temperature. The fixing film FF at the third temperature may have a rigidity less than a rigidity of the fixing film FF at the second temperature.

The fixing film FF may be separated from the chip stack including the plurality of first to fourth semiconductor chips 110 to 140 and the molding layer 200. The viscoelasticity of the fixing film FF may allow the fixing film FF to separate without significant damage to the chip stack including the plurality of first to fourth semiconductor chips 110 to 140 and the molding layer 200.

Alternatively or additionally, after the separation of the fixing film FF, a residue of the fixing film FF may remain on the chip stack including the plurality of first to fourth semiconductor chips 110 to 140 and/or the molding layer 200. A washing process that uses an organic solvent may be performed to remove the residual fixing film RF of the fixing film FF. The residual fixing film RF may be dissolved in the organic solvent, thereby being removed.

In a method of fabricating a semiconductor package, according to the present disclosure, the fixing film FF may be used to stably fix a semiconductor device having an asymmetric structure and/or a large step difference. The fixing film FF may have different physical properties at each of the first to third temperatures. Thus, the fixing film FF may be separated without damage to the semiconductor device while stably fixing the semiconductor device.

In a method of fabricating a semiconductor package, according to the present disclosure, a fixing film including a paraffin-based compound may be used to stably fix a semiconductor device having a step difference. The fixing film may have an elastic modulus that is changed depending on temperature. In a heated state at a first temperature, the fixing film may be impregnated to the semiconductor device, and at a second temperature (e.g., room temperature), the fixing film may be solidified to fix the semiconductor device. Subsequently, in a reheated state at a third temperature, the fixing film may be separated from the semiconductor device without significant damage to the semiconductor device. Therefore, the semiconductor device having a large step difference may be fixed by the fixing film and stably transported to undergo a subsequent process, and the fixing film may be separated without significant damage to the semiconductor device. In addition, the used fixing film may be reusable to further reduce costs of fabricating semiconductor packages.

Although the present disclosure has been described in connection with the some embodiments of the present disclosure illustrated in the accompanying drawings, it is to be understood by one of ordinary skill in the art that variations in form and detail may be made therein without departing from the spirit and essential feature of the present disclosure. The above disclosed embodiments should thus be considered illustrative and not restrictive.

What is claimed is:

1. A method of fabricating a semiconductor package, the method comprising:
preparing a semiconductor device comprising a plurality of step structures;
covering, at a first temperature, a portion of the plurality of step structures with a fixing film;
fixing the fixing film on the portion of the plurality of step structures by performing, at a second temperature, an annealing process on the fixing film; and
separating, at a third temperature, at least a portion of the fixing film from the semiconductor device,
wherein each of the first temperature and the third temperature is greater than the second temperature,
wherein the fixing film comprises a paraffin-based compound, and
wherein the fixing film at each of the first temperature and the third temperature has an elastic modulus less than an elastic modulus of the fixing film at the second temperature.

2. The method of claim 1, wherein a softening point of the fixing film has a range of 60 degrees Celsius (°C.) to 90° C.

3. The method of claim 1, wherein the covering of the portion of the plurality of step structures with the fixing film comprises:
providing, at the second temperature, the fixing film between adjacent step structures of the plurality of step structures.

4. The method of claim 1, wherein a ratio of a distance between adjacent step structures of the plurality of step structures to a height of the plurality of step structures has a range of 3 to 10.

5. The method of claim 1, wherein the second temperature is less than a softening point of the fixing film.

6. The method of claim 1, further comprising:
removing a portion of the fixing film remaining on the semiconductor device by providing an organic solvent.

7. The method of claim 1, wherein a thickness of the fixing film has a range of 50 micrometers (μm) to 500 μm.

8. The method of claim 1, wherein a carbon number of the fixing film has a range of 15 to 150.

9. The method of claim 1, wherein, at each of the first temperature and the third temperature, the fixing film has viscoelasticity.

10. The method of claim 1, wherein the fixing film at the second temperature has a rigidity greater than a rigidity of the fixing film at each of the first temperature and the third temperature.

11. The method of claim 1, wherein the covering of the portion of the plurality of step structures with the fixing film comprises:
providing a base film on the fixing film,
wherein the base film comprises at least one of polyethylene (PE), polypropylene (PP), polyvinyl chloride (PVC), polyethylene terephthalate (PET), polycarbonate (PC), polyamide (PA), polyolefin (PO), polyethylene naphthalate (PEN), or polyetheretherketone (PEEK).

12. The method of claim 11, wherein a thickness of the base film has a range of 50 micrometers (μm) to 100 μm.

13. A method of fabricating a semiconductor package, the method comprising:
preparing a semiconductor device comprising a plurality of step structures;
covering, at a first temperature, a portion of the plurality of step structures with a fixing film;
fixing the fixing film on the portion of the plurality of step structures by performing, at a second temperature, an annealing process on the fixing film; and
separating, at a third temperature, at least a portion of the fixing film from the semiconductor device,
wherein the fixing film comprises a paraffin-based compound,
wherein a thickness of the fixing film has a range of 50 micrometers (μm) to 500 μm, and
wherein a carbon number of the fixing film has a range of 15 to 150.

14. The method of claim 13, wherein a softening point of the fixing film has a range of 60 degrees Celsius (°C.) to 90° C.

15. The method of claim 13, wherein each of the first temperature and the third temperature is greater than the second temperature, and
wherein the second temperature is less than a softening point of the fixing film.

16. The method of claim 13, wherein the covering of the portion of the plurality of step structures with the fixing film comprises:
providing, at the second temperature, the fixing film between adjacent step structures of the plurality of step structures.

17. The method of claim 13, further comprising:
removing a portion of the fixing film remaining on the semiconductor device by providing an organic solvent.

18. The method of claim 13, wherein the covering of the portion of the plurality of step structures with the fixing film comprises:
providing a base film on the fixing film,
wherein the base film comprises at least one of polyethylene (PE), polypropylene (PP), polyvinyl chloride (PVC), polyethylene terephthalate (PET), polycarbonate (PC), polyamide (PA), polyolefin (PO), polyethylene naphthalate (PEN), or polyetheretherketone (PEEK).

19. The method of claim 18, wherein a thickness of the base film has a range of 50 μm to 100 μm.

20. A method of fabricating a semiconductor package, the method comprising:
forming a chip stack comprising a plurality of semiconductor chips that are stepwise stacked along a first direction;
providing, at a first temperature, the chip stack on a surface of a fixing film;
fixing the chip stack to the fixing film by annealing, at a second temperature, the fixing film;
forming a plurality of wires on the chip stack;
forming a molding layer at least partially covering the chip stack;
forming a redistribution pattern on the molding layer;
forming a plurality of connection terminals on the redistribution pattern; and
separating, at a third temperature, at least a portion of the fixing film from the chip stack,
wherein the fixing film comprises a paraffin-based compound,
wherein each of the first temperature and the third temperature is greater than the second temperature, and
wherein the second temperature is less than a softening point of the fixing film.
